(19) United States
(12) Patent Application Publication
(10) Pub. No.: US 2025/0113658 A1
(43) Pub. Date: Apr. 3, 2025

(54) LIGHT-EMITTING DIODE CHIP, MANUFACTURING METHOD THEREOF, AND DISPLAY

(71) Applicant: Xiamen Extremely PQ Display Technology Co., Ltd., Xiamen, Fujian (CN)

(72) Inventor: Yanxi YE, Xiamen, Fujian (CN)

(73) Assignee: Xiamen Extremely PQ Display Technology Co., Ltd., Xiamen, Fujian (CN)

(21) Appl. No.: 18/832,117

(22) PCT Filed: Dec. 22, 2022
(86) PCT No.: PCT/CN2022/141127

§ 371 Date: Jul. 23, 2024

(51) Int. Cl. H10H 20/814; H10H 20/01; H10H 20/831; H10H 20/857

(52) U.S. Cl. CPC H10H 20/814; H10H 20/032; H10H 20/8312; H10H 20/857

(57) ABSTRACT

A light-emitting diode chip, a manufacturing method thereof, and a display are provided. The light-emitting diode chip includes a first epitaxial light-emitting structure; a reflective layer at a side of the first epitaxial light-emitting structure; a second epitaxial light-emitting structure located at a side of the reflective layer which faces away from the first epitaxial light-emitting structure; and a first polar electrode and a second polar electrode electrically connecting semiconductor layers having first polarities and semiconductor layers having second polarities in the first epitaxial light-emitting structure and the second epitaxial light-emitting structure, respectively.

### TECHNICAL FIELD

The present application relates to the field of displaying technologies, and more particularly, to a light-emitting diode chip, a manufacturing method thereof, and a display.

### BACKGROUND

The double-sided displaying technology is an important application of the novel displaying technology, especially in the public displaying field, so that a person on the scene can obtain the information, whether the person is in front of the display screen or in back of the display screen, thereby greatly improving the utilization rate of the public site.

However, the conventional double-sided displaying technology generally achieves a double-sided displaying function by bonding two single-sided display screens, each of which contains a light-emitting diode backplane. Thus, there are problems such as overall thicker thickness, heavy weight, high production cost and the like of the double-sided display panel, which is unfavorable for improving market competitiveness of the product.

### SUMMARY

### Technical Problem

The present application provides a light-emitting diode chip, a manufacturing method thereof, and a display to reduce the thickness, the weight, and the cost of a double-sided display, thereby improving market competitiveness of a product.

### Problem Solution

### Technical Solution

To solve the above problems, embodiments of the present application provide a light-emitting diode chip. The light-emitting diode chip includes: a first epitaxial light-emitting structure including a first semiconductor layer, a first light-emitting layer, and a second semiconductor layer stacked in sequence; a reflective layer at a side of the first epitaxial light-emitting structure; a second epitaxial light-emitting structure located at a side of the reflective layer which faces away from the first epitaxial light-emitting structure, and including a third semiconductor layer, a second light-emitting layer, and a fourth semiconductor layer that are sequentially stacked, in which the first semiconductor layer and the third semiconductor layer have first polarities, and the second semiconductor layer and the fourth semiconductor layer have second polarities; a first polar electrode electrically connecting the first semiconductor layer and the third semiconductor layer; and a second polar electrode electrically connecting the second semiconductor layer and the fourth semiconductor layer.

The light-emitting diode chip further includes a first Bragg reflective layer between the first epitaxial light-emitting structure and the reflective layer; and a second Bragg reflective layer between the second epitaxial light-emitting structure and the reflective layer.

The first polar electrode includes a first extension portion extending from a sidewall of the third semiconductor layer along a sidewall of a first film layer structure to the first semiconductor layer, in which the first film layer structure is a film layer structure between the first semiconductor layer and the third semiconductor layer; the second polar electrode includes a second extension portion extending from a sidewall of the fourth semiconductor layer along a sidewall of a second film layer structure to the second semiconductor layer, in which the second film layer structure is a film layer structure between the second semiconductor layer and the fourth semiconductor layer.

The sidewall of the third semiconductor layer, a sidewall of the first film layer structure, and a sidewall of the first semiconductor layer are connected together to form a first step structure, a step surface of the first step structure is the first semiconductor layer, and the first extension portion extends from the sidewall of the third semiconductor layer along the sidewall of the first film layer structure to the step surface of the first step structure.

The sidewall of the fourth semiconductor layer, a sidewall of the second film layer structure, and a sidewall of the second semiconductor layer are connected together to form a second step structure, a step surface of the second step structure is the second semiconductor layer, and the second extension portion extends from the sidewall of the fourth semiconductor layer to the step surface of the second step structure along the sidewall of the second film layer structure.

The first polar electrode further includes a first contact portion connected to the first extension portion and in contact with a surface of the third semiconductor layer which faces away from the reflective layer; the second polar electrode further includes a second contact portion connected to the second extension portion and in contact with a surface of the fourth semiconductor layer which faces away from the reflective layer.

The light-emitting diode chip further includes: a first insulating layer that is located between the first extension portion and the first film layer structure and electrically isolates the first extension portion from the first film layer structure; and a second insulating layer that is located between the second extension portion and the second film layer structure, and that electrically isolates the second extension portion from the second film layer structure.

The light-emitting diode chip further includes a first interlayer via extending through the third semiconductor layer and a film layer structure located between the third semiconductor layer and the first semiconductor layer, in which the first polar electrode is located on a surface of the third semiconductor layer which faces away from the reflective layer and electrically connected to the first semiconductor layer through the first interlayer via; and a second interlayer via extending through the fourth semiconductor layer and a film layer structure between the fourth semiconductor layer and the second semiconductor layer, in which the second polar electrode is located on a surface of the fourth semiconductor layer which faces away from the reflective layer and electrically connected to the second semiconductor layer through the second interlayer via.

In order to solve the above problems, the embodiments of the present application further provide a manufacturing method of a light-emitting diode chip including: forming a light-emitting diode epitaxial wafer including a substrate, a first epitaxial light-emitting structure, a reflective layer and a second epitaxial light-emitting structure, in which the first epitaxial light-emitting structure is formed on a side of the substrate and includes a first semiconductor layer, a first light-emitting layer and a second semiconductor layer, in which the reflective layer is formed on a side of the first epitaxial light-emitting structure which faces away from the substrate, and the second epitaxial light-emitting structure is formed on a side of the reflective layer which faces away from the first epitaxial light-emitting structure and comprises a third semiconductor layer, a second light-emitting layer and a fourth semiconductor layer, in which the first semiconductor layer and the third semiconductor layer have first polarities and the second semiconductor layer and the fourth semiconductor layer have second polarities; forming a first polar electrode electrically connecting the first semiconductor layer and the third semiconductor layer; and forming a second polar electrode electrically connecting the second semiconductor layer and the fourth semiconductor layer.

The forming the first polar electrode includes: forming a first extension portion to obtain the first polar electrode including the first extension portion, in which the first extension portion extends from a sidewall of the third semiconductor layer along a sidewall of a first film layer structure to the first semiconductor layer, the first film layer structure is a film layer structure between the first semiconductor layer and the third semiconductor layer; the forming the second polar electrode includes: forming a second extension portion to obtain the second polar electrode including the second extension portion, in which the second extension portion extends from a sidewall of the fourth semiconductor layer along a sidewall of a second film layer structure to the second semiconductor layer, the second film layer structure is a film layer structure between the second semiconductor layer and the fourth semiconductor layer.

Before forming the first polar electrode, the manufacturing method further includes: forming a first interlayer via extending through the third semiconductor layer and a film layer structure between the third semiconductor layer and the first semiconductor layer; the forming the first polar electrode includes: forming the first polar electrode filling the first interlayer via on a surface of the third semiconductor layer which faces away from the reflective layer.

Before forming the second polar electrode, the manufacturing method further includes: forming a second interlayer via extending through the fourth semiconductor layer and a film layer structure between the fourth semiconductor layer and the second semiconductor layer; the forming the second polar electrode includes: forming the second polar electrode filling the interlayer via on a surface of the fourth semiconductor layer which faces away from the reflective layer.

In order to solve the above problems, the embodiments of the present application further provide a light-emitting diode display including: a driving substrate; and the above-mentioned light-emitting diode chip; in which the light-emitting diode chip is electrically connected to the driving substrate, and the driving substrate is configured to drive the light-emitting diode chip to emit light.

The light-emitting diode display further includes: a pixel defining layer provided on a side of the driving substrate, in which a side of the pixel defining layer which faces away from the driving substrate is provided with a groove, and at least a part of the light-emitting diode chip is located in the groove; a first bonding electrode disposed on an inner wall of the groove and electrically connected to the first polar electrode of the light-emitting diode chip; and a second bonding electrode disposed on the inner wall of the groove and electrically connected to the second polar electrode of the light-emitting diode chip.

### Beneficial Effect of Application

### Beneficial Effect

Advantageous effects of the present application are as follows. According to the light-emitting diode chip, a manufacturing method of the light-emitting diode chip, and a display provided in the present application, two epitaxial light-emitting structures are provided in a single light-emitting diode chip, and a reflective layer is provided between the two epitaxial light-emitting structures. So, the single light-emitting diode chip has a double-sided light-emitting characteristic. In this way, the light-emitting diode display may realize the double-sided displaying function by using one light-emitting diode backplane, which greatly reduces the thickness, the weight, and the cost of the double-sided display, and is beneficial to improving the market competitiveness of a product.

### BRIEF DESCRIPTION OF THE DRAWINGS

### Description of Drawings

In order that the specific embodiments of the present application or the technical solutions in the prior art may be described more clearly, reference will now be made to the accompanying drawings required for the description of the specific embodiments or the prior art. It will be apparent that the accompanying drawings in the following description are some of the embodiments of the present application, and other drawings may be made to those skilled in the art without involving any inventive effort.

The components in the drawings are not drawn to scale, but are merely intended to illustrate the principles of the present application. In order to facilitate illustration and description of portions of the present application, corresponding portions in the drawings may be exaggerated, i.e., made larger relative to other components in the exemplary apparatus actually manufactured in accordance with the present application. In the drawings, the same or similar features or components will be denoted by the same or similar reference numerals.

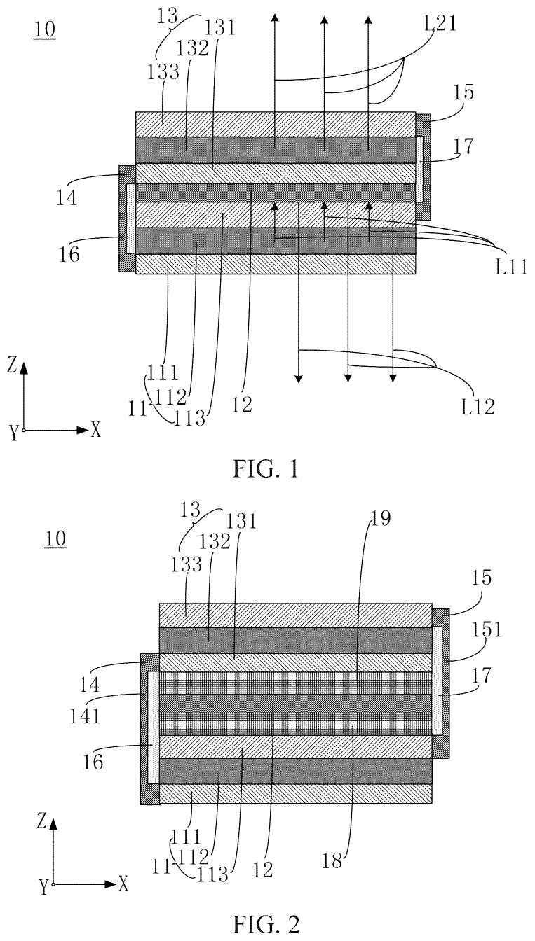

FIG. 1 is a schematic diagram of a cross-sectional structure of a light-emitting diode chip according to embodiments of the present application;

FIG. 2 is another schematic diagram of a cross-sectional structure of a light-emitting diode chip according to embodiments of the present application;

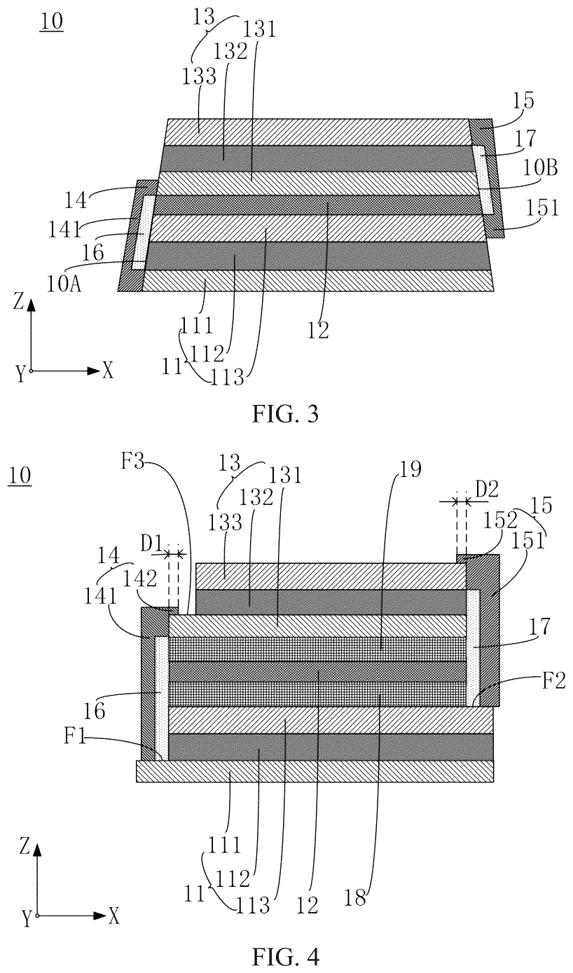

FIG. 3 is yet another schematic diagram of a cross-sectional structure of a light-emitting diode chip according to embodiments of the present application;

FIG. 4 is yet another schematic diagram of a cross-sectional structure of a light-emitting diode chip according to embodiments of the present application;

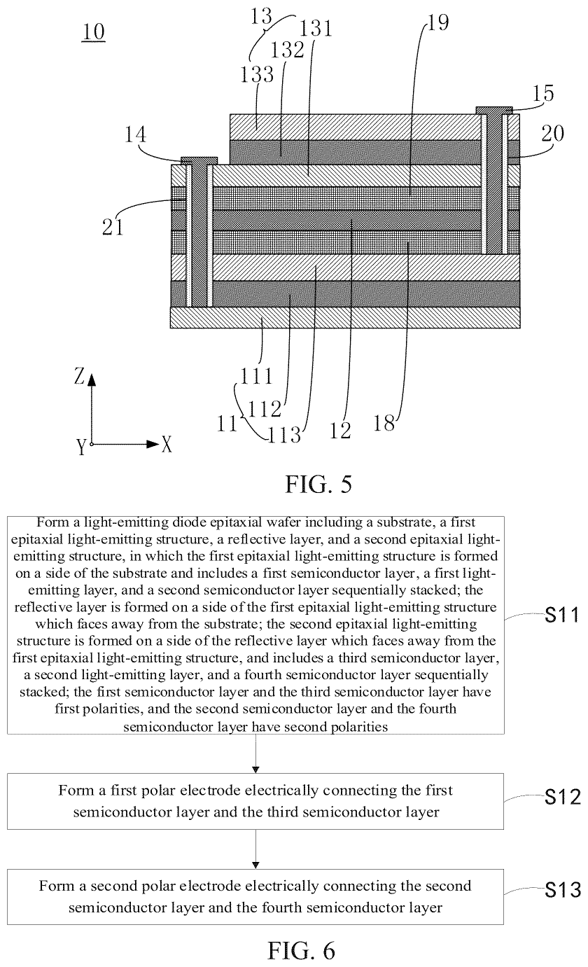

FIG. 5 is yet another schematic diagram of a cross-sectional structure of a light-emitting diode chip according to embodiments of the present application;

FIG. 6 is a schematic flow diagram of a manufacturing method of a light-emitting diode chip according to embodiments of the present application;

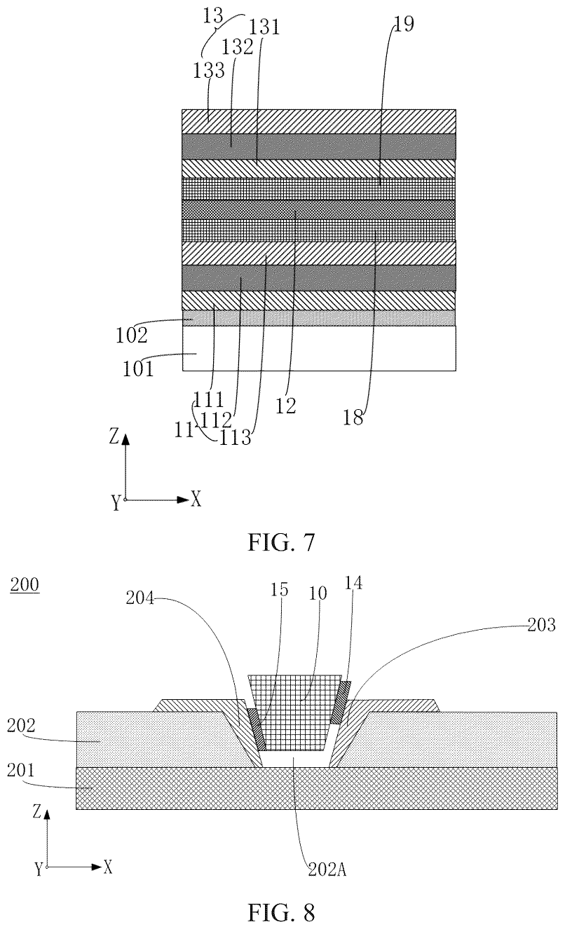

FIG. 7 is a schematic diagram of a cross-sectional structure of a light-emitting diode epitaxial wafer according to embodiments of the present application; and

FIG. 8 is a schematic diagram of a cross-sectional structure of a light-emitting diode display according to embodiments of the present application.

### EMBODIMENTS OF APPLICATION

### Implementation of the Present Application

The present application is described in further detail below with reference to the accompanying drawings and the examples. It is specifically noted that the following examples are intended to illustrate the present application only, but do not limit the scope of the application. Similarly, the following examples are only a part and not all of the examples of the present application, and all other examples obtained by one of ordinary skill in the art without involving any inventive effort are within the scope of the present application.

In addition, when describing the structure of a component, when one layer or one region is referred to as being “on” or “above” another layer or another region, it can mean that it is directly on the another layer or the another region; or there are other layers or regions between the one layer or the one region between the another layer or the another region. And, if the component is turned over, the one layer or the one region will be “under” or “beneath” the another layer or the another region. Furthermore, the features, the structures, or the characteristics described below may be combined in any suitable manner in one or more embodiments.

Referring to FIG. 1, FIG. 1 is a schematic diagram of a cross-sectional structure of a light-emitting diode chip according to embodiments of the present application. As shown in FIG. 1, the light-emitting diode chip 10 includes a first epitaxial light-emitting structure 11, a reflective layer 12 provided on a side of the first epitaxial light-emitting structure 11, and a second epitaxial light-emitting structure 13 provided on a side of the reflective layer 12 which faces away from the first epitaxial light-emitting structure 11. The first epitaxial light-emitting structure 11 includes a first semiconductor layer 111, a first light-emitting layer 112, and a second semiconductor layer 113 that are sequentially stacked. The second epitaxial light-emitting structure 13 includes a third semiconductor layer 131, a second light-emitting layer 132, and a fourth semiconductor layer 133 that are sequentially stacked. The first semiconductor layer 111 and the third semiconductor layer 131 each have a first polarity, and the second semiconductor layer 113 and the fourth semiconductor layer 133 each have a second polarity.

In some embodiments, the first semiconductor layer 111 and the third semiconductor layer 131 may be one of an N-type semiconductor layer and a P-type semiconductor layer, and the second semiconductor layer 113 and the fourth semiconductor layer 133 may be the other of an N-type semiconductor layer and a P-type semiconductor layer. The N-type semiconductor layer may be specifically an N-type gallium nitride layer or an N-type gallium arsenide layer, and the P-type semiconductor layer may be specifically a P-type gallium nitride layer or a P-type aluminum gallium nitride layer.

Specifically, the first light-emitting layer 112 and the second light-emitting layer 132 may be quantum well layers, for example, indium gallium nitride quantum well layers, or may be a multilayer quantum well layers of indium gallium nitride/gallium nitride. The material of the reflective layer 12 may include any material having a high reflectivity (e.g., greater than 50%) for visible light, such as metals, alloys, and the like.

In some embodiments, as shown in FIG. 1, the second semiconductor layer 113 may be located between the reflective layer 12 and the first light-emitting layer 112, and the third semiconductor layer 131 may be located between the reflective layer 12 and the second light-emitting layer 132. That is, the first epitaxial light-emitting structure 11 and the second epitaxial light-emitting structure 13 may each be a front-mounted structure or an inverted structure. Specifically, the first semiconductor layer 111, the first light-emitting layer 112, the second semiconductor layer 113, the reflective layer 12, the third semiconductor layer 131, the second light-emitting layer 132, and the fourth semiconductor layer 133 may be stacked in sequence in a first direction Z. The first semiconductor layer 111, the second semiconductor layer 113, the third semiconductor layer 131, and the fourth semiconductor layer 133 may be an N-type semiconductor layer, a P-type semiconductor layer, an N-type semiconductor layer, and a P-type semiconductor layer, respectively; or may be a P-type semiconductor layer, an N-type semiconductor layer, a P-type semiconductor layer, and an N-type semiconductor layer, respectively.

In some other embodiments, the first epitaxial light-emitting structure 11 may be one of a front-mounted structure and an inverted structure, and the second epitaxial light-emitting structure 13 may be the other of the front-mounted structure and the inverted structure. For example, the first semiconductor layer 111, the second semiconductor layer 113, the fourth semiconductor layer 133, and the third semiconductor layer 131 may be an N-type semiconductor layer, a P-type semiconductor layer, a P-type semiconductor layer, and an N-type semiconductor layer, respectively; or may be a P-type semiconductor layer, an N-type semiconductor layer, an N-type semiconductor layer, and a P-type semiconductor layer, respectively.

In the present embodiments, as shown in FIG. 1, most of the light rays L11 or a small part of the light rays L11 emitted by the first epitaxial light-emitting structure 11 are reflected after being transmitted to the reflective layer 12 to form the reflected light L12. The reflected light L12 is transmitted outwardly toward a side of the first epitaxial light-emitting structure 11 which faces away from the reflective layer 12. In addition, a remaining portion of the light rays emitted by the first epitaxial light-emitting structure 11 may be transmitted outwardly in a direction of facing away from the reflective layer 12. Therefore, the light-emitting diode chip 10 can emit light at the side of the first epitaxial light-emitting structure 11 which faces away from the reflective layer 12.

At the same time, most of the light rays L21 or a small part of the light rays L21 emitted by the second epitaxial light-emitting structure 13 may be transmitted outwardly directly in a direction of facing away from the reflective layer 12. A remaining portion of the light rays may be reflected by the reflective layer 12 after being transmitted to the reflective layer 12. The reflected light transmits outwardly toward a side of the second epitaxial light-emitting structure 13 which faces away from the reflective layer 12. Therefore, the light-emitting diode chip 10 may emit light at the side of the second epitaxial light-emitting structure 13 which faces away from the reflective layer 12.

Further, it should be noted that in the present embodiments, two epitaxial light-emitting structures 11/13 are provided in the single light-emitting diode chip 10, and the reflective layer 12 is provided between the two epitaxial light-emitting structures 11/13. So, the single light-emitting diode chip 10 has a double-sided light-emitting characteristic. In this way, the light-emitting diode displaying function may be realized by using the single light-emitting diode backplane, which greatly reduces the thickness, the weight, and the cost of the double-sided display, and further facilitates improvement of the market competitiveness of the product.

In some embodiments, as shown in FIG. 2, the light-emitting diode chip 10 may further include a first Bragg reflective layer 18 and a second Bragg reflective layer 19. The first Bragg reflective layer 18 is located between the first epitaxial light-emitting structure 11 and the reflective layer 12; and the second Bragg reflective layer 19 is located between the second epitaxial light-emitting structure 13 and the reflective layer 12. The first Bragg reflective layer 18 and the second Bragg reflective layer 19 are capable of increasing the reflectivity of the reflective layer 12 on the light, thereby being capable of increasing the light extraction efficiency of the light-emitting diode chip 10.

Specifically, the first Bragg reflective layer 18 and the second Bragg reflective layer 19 may be Distributed Bragg Reflector (referred briefly to as DBR). That is, the first Bragg reflective layer 18 and the second Bragg reflective layer 19 may be formed by stacking materials having different refractive indices.

In the above-described embodiment, as shown in FIGS. 1 and 2, the light-emitting diode chip 10 may further include a first polar electrode 14 electrically connected to the first semiconductor layer 111 and the third semiconductor layer 131 having the same first polarity; and a second polar electrode 15 electrically connected to the second semiconductor layer 113 and the fourth semiconductor layer 133 having the same second polarity. In this way, the parallel connection of the first epitaxial light-emitting structure 11 and the second epitaxial light-emitting structure 13 may be realized, thereby facilitating reduction of luminance difference of double-sided light emission of the light-emitting diode chip 10.

In some embodiments, in order to reduce the shielding of the light rays emitted from the light-emitting diode chip 10 by the first polar electrode 14, as shown in FIGS. 1 and 2, a part of the first polar electrode 14 or the whole first polar electrode 14 may be provided on a sidewall of the first semiconductor layer 111, a sidewall of the third semiconductor layer 131, and a sidewall of a first film layer structure. The first film layer structure is a film layer structure between the first semiconductor layer 111 and the third semiconductor layer 131.

Specifically, the first polar electrode 14 may include a first extension portion 141 that may extend from the sidewall of the third semiconductor layer 131 to the first semiconductor layer 111 along the sidewall of the first film layer structure, so as to achieve electrical connection between the first semiconductor layer 111 and the third semiconductor layer 131.

Accordingly, as shown in FIGS. 1 and 2, the light-emitting diode chip 10 may further include a first insulating layer 16. The first insulating layer 16 may be provided between the first film layer structure and the first polar electrode 14, and be capable of electrically isolating the first film layer structure from the first polar electrode 14, so as to avoid the electric leakage between semiconductor layers of different polarities.

In some embodiments, in order to reduce the shielding of the light rays emitted from the light-emitting diode chip 10 by the second polar electrode 15, as shown in FIGS. 1 and 2, a part of the second polar electrode 15 or the whole the second polar electrode 15 may be provided on the sidewall of the second semiconductor layer 113, the sidewall of the fourth semiconductor layer 133, and the sidewall of the second film layer structure. The second film layer structure is a film layer structure between the second semiconductor layer 113 and the fourth semiconductor layer 133.

Specifically, the second polar electrode 15 may include a second extension portion 151 that may extend from the sidewall of the fourth semiconductor layer 133 to the second semiconductor layer 113 along the sidewall of the second film layer structure, so as to achieve electrical connection between the second semiconductor layer 113 and the fourth semiconductor layer 133.

Accordingly, as shown in FIGS. 1 and 2, the light-emitting diode chip 10 may further include a second insulating layer 17. The second insulating layer 17 may be provided between the second film layer structure and the second polar electrode 15, and may be capable of electrically isolating the second film layer structure from the second polar electrode 15, so as to avoid the electric leakage between semiconductor layers of different polarities.

In some specific embodiments, as shown in FIG. 3, the sidewall of the first semiconductor layer 111, the sidewall of the third semiconductor layer 131, and the sidewall of the first film layer structure may be connected together to form an inclined sidewall 10A. The first extension portion 141 of the first polar electrode 14 may be formed on the inclined sidewall 10A to increase the adhesion force of the first polar electrode 14, thereby facilitating improvement of the stability and the reliability of the light-emitting diode chip 10.

Similarly, the sidewall of the second semiconductor layer 113, the sidewall of the fourth semiconductor layer 133, and the sidewall of the second film layer structure may be connected together to form the inclined sidewall 10B. The second extension portion 151 of the second polar electrode 15 may be formed on the inclined sidewall 10B to increase the adhesion force of the second polar electrode 15, thereby facilitating improvement of the stability and the reliability of the light-emitting diode chip 10.

In some examples, as shown in FIG. 3, the light-emitting diode chip 10 may be a trapezoidal-like structure as a whole.

In some specific embodiments, as shown in FIG. 4, in order to further increase the adhesion force of the first polar electrode 14, the sidewall of the third semiconductor layer 131, the sidewall of the first film layer structure, and the sidewall of the first semiconductor layer 111 may be connected together to form a first step structure. A step surface F1 of the first step structure may be the first semiconductor layer 111. Further, the first extension portion 141 of the first polar electrode 14 may extend from the sidewall of the third semiconductor layer 131 along the sidewall of the first film layer structure to the step surface F1 of the first step structure, and be in contact with the surface of the first semiconductor layer 111 which faces towards the reflective layer 12.

In some specific embodiments, as shown in FIG. 4, to further increase the adhesion force of the second polar electrode 15, the sidewall of the fourth semiconductor layer 133, the sidewall of the second film layer structure, and the sidewall of the second semiconductor layer 113 may be connected together to form a second step structure. A step surface F2 of the second step structure may be the second semiconductor layer 113. Further, the second extension portion 151 of the second polar electrode 15 may extend from the sidewall of the fourth semiconductor layer 133 along the sidewall of the second film layer structure to the step surface F2 of the second step structure, and be in contact with the surface of the second semiconductor layer 113 which faces towards the reflective layer 12.

Further, in order to increase the adhesion force of the first polar electrode 14 on the third semiconductor layer 131, the first polar electrode 14 may further include a first contact portion 142 connected to the first extension portion 141. The first contact portion 142 may be in contact with a surface of the third semiconductor layer 131 which faces away from the reflective layer 12.

Specifically, in the embodiment in which the third semiconductor layer 131 is located between the reflective layer 12 and the second light-emitting layer 132, as shown in FIG. 4, the sidewall of the third semiconductor layer 131, the sidewall of the second light-emitting layer 132, and the sidewall of the fourth semiconductor layer 133 may be connected together to form a third step structure. A step surface F3 of the third step structure may be the third semiconductor layer 131. Further, the first contact portion 142 of the first polar electrode 14 may be located on the step surface F3 of the third step structure, and be in contact with the surface of the third semiconductor layer 131 which faces away from the reflective layer 12.

Further, in order to reduce the shielding of the light rays emitted from the light-emitting diode chip 10 by the first contact portion 142, there is a distance D1 of 5 μm or less by which the first contact portion 142 extends in a direction in which the sidewall of the third semiconductor layer 131 directs toward an inside of the third semiconductor layer 131.

In some specific embodiments, as shown in FIG. 4, in order to increase the adhesion force of the second polar electrode 15 on the fourth semiconductor layer 133, the second polar electrode 15 may further include a second contact portion 152 connected to the second extension portion 151. The second contact portion 152 may be in contact with a surface of the fourth semiconductor layer 133 which faces away from the reflective layer 12.

Specifically, the sidewall of the fourth semiconductor layer 133, the sidewall of the second light-emitting layer 132, and the sidewall of the third semiconductor layer 131 may be connected together to form a fourth step structure. A step surface of the fourth step structure may be the fourth semiconductor layer 133. Further, the second contact portion 152 of the second polar electrode 15 may be located on the step surface of the fourth step structure, and be in contact with the surface of the fourth semiconductor layer 133 which faces away from the reflective layer 12.

In particular embodiments, in order to reduce the shielding of the light rays emitted from the light-emitting diode chip 10 by the second contact portion 152, there is a distance D2 of 5 μm or less by which the second contact portion 152 extends in a direction in which the sidewall of the fourth semiconductor layer 133 directs toward an inside of the fourth semiconductor layer 133.

In some embodiments, the material of the first polar electrode 14 and the second polar electrode 15 may include a conductive material such as a metal or metal oxide. The materials of both the first insulating layer 16 and the second insulating layer 17 may include insulating materials such as silicon nitride, silicon oxide, or silicon oxynitride.

In some embodiments in which a structure of disposing a part of first polar electrode 14 or the whole first polar electrode 14 on the sidewall of the first semiconductor layer 111, the sidewall of the third semiconductor layer 131, and the sidewall of the first film layer structure is replaced, as shown in FIG. 5, the first polar electrode 14 may also be formed on a surface of the second epitaxial light-emitting structure 13 which faces away from the reflective layer 12, and the first polar electrode 14 may be a transparent electrode. The first polar electrode 14 may be made of a transparent conductive material such as indium tin oxide (ITO). In this way, it may decrease the shielding of the first polar electrode 14 on the light emission of the second epitaxial light-emitting structure 13, thereby improving the light extraction efficiency of the light-emitting diode chip 10.

Specifically, as shown in FIG. 5, the light-emitting diode chip 10 may further include a first interlayer via 21 extending through the third semiconductor layer 131 and a film layer structure (i.e., a first film layer structure) between the third semiconductor layer 131 and the first semiconductor layer 111. The first polar electrode 14 may be located on a surface of the third semiconductor layer 131 which faces away from the reflective layer 12, and may be electrically connected to the first semiconductor layer 111 through the first interlayer via 21.

In examples, a third insulating layer may be provided on an inner sidewall of the first interlayer via 21 to avoid electric leakage.

In some embodiments in which a structure of disposing a part of second polar electrode 15 or the whole second polar electrode 15 on the sidewall of the second semiconductor layer 113 is replaced, the sidewall of the fourth semiconductor layer 133, and the sidewall of the second film layer structure, as shown in FIG. 5, the second polar electrode 15 may also be formed on a surface of the second epitaxial light-emitting structure 13 which faces away from the reflective layer 12, and the second polar electrode 15 may be a transparent electrode. The second polar electrode 15 may be made of a transparent conductive material such as indium tin oxide (ITO). In this way, it may reduce the shielding of the second polar electrode 15 on the light emission of the second epitaxial light-emitting structure 13, thereby improving the light extraction efficiency of the light-emitting diode chip 10.

Specifically, as shown in FIG. 5, the light-emitting diode chip 10 may further include a second interlayer via 20 extending through the fourth semiconductor layer 133 and a film layer structure (i.e., a second film layer structure) between the fourth semiconductor layer 133 and the second semiconductor layer 113. The second polar electrode 15 may be located on a surface of the fourth semiconductor layer 133 which faces away from the reflective layer 12, and may be electrically connected to the second semiconductor layer 113 through the second interlayer via 20.

In examples, a fourth insulating layer may be provided on the inner sidewall of the second interlayer via 20 to avoid electric leakage.

In the above embodiments, the light-emitting diode chip 10 may be specifically a Micro-Light Emitting Diode (Micro-LED) chip, so that a double-sided light-emitting Micro-LED chip may be obtained.

As may be seen from the above, according to the light-emitting diode chip provided in the embodiments of the present application, two epitaxial light-emitting structures are provided in the single light-emitting diode chip, and the reflective layer is provided between the two epitaxial light-emitting structures. In this way, the single light-emitting diode chip has a double-sided light-emitting characteristic, and the light-emitting diode displaying function may be realized by using one light-emitting diode backplane, which greatly reduces the thickness, the weight, and the cost of the double-sided display, and is beneficial to improving the market competitiveness of a product.

Referring to FIG. 6, FIG. 6 is a schematic flow diagram of a manufacturing method of a light-emitting diode chip according to embodiments of the present application. Referring to FIGS. 1 to 5 and FIG. 7, FIGS. 1 to 5 and FIG. 7 are schematic structural diagrams of a manufacturing method of a light-emitting diode chip according to embodiments of the present application. In the present embodiments, the manufacturing method of the light-emitting diode chip 10 is described as an example. A specific flow of the manufacturing method of the light-emitting diode chip 10 may be as follows.

At step S11, a light-emitting diode epitaxial wafer (as shown in FIG. 7) including a substrate 101, a first epitaxial light-emitting structure 11, a reflective layer 12, and a second epitaxial light-emitting structure 13 is formed, in which the first epitaxial light-emitting structure 11 is formed on a side of the substrate 101 and includes a first semiconductor layer 111, a first light-emitting layer 112, and a second semiconductor layer 113 sequentially stacked; the reflective layer 12 is formed on a side of the first epitaxial light-emitting structure 11 which faces away from the substrate 101; the second epitaxial light-emitting structure 13 is formed on a side of the reflective layer 12 which faces away from the first epitaxial light-emitting structure 11, and includes a third semiconductor layer 131, a second light-emitting layer 132, and a fourth semiconductor layer 133 sequentially stacked; the first semiconductor layer 111 and the third semiconductor layer 131 have first polarities, and the second semiconductor layer 113 and the fourth semiconductor layer 133 have second polarities.

In some embodiments, as shown in FIG. 7, the light-emitting diode epitaxial wafer may further include a buffer layer 102 formed on a side of the substrate 101. The first epitaxial light-emitting structure 11 may be specifically formed on a side of the buffer layer 102 which faces away from the substrate 101. The substrate 101 may be a sapphire substrate, a silicon substrate, a silicon carbide substrate, or the like. The material of the buffer layer 102 may include a buffer material such as silicon nitride, silicon oxide, gallium nitride, or aluminum nitride.

Also, it should be noted that in order to avoid that the brightness of the side of the first epitaxial light-emitting structure 11 which faces away from the reflective layer 12 decreases due to the absorption of the light rays emitted by the first epitaxial light-emitting structure 11 by the substrate 101 and/or the buffer layer 102, the substrate 101 and/or the buffer layer 102 may be removed in a subsequent processing step. Specifically, the substrate 101 and/or the buffer layer 102 may be peeled off in a laser peeling process.

At step S12, a first polar electrode 14 (as shown in FIGS. 1 to 5) electrically connecting the first semiconductor layer 111 and the third semiconductor layer 131 is formed.

In some embodiments, as shown in FIGS. 1 to 4, step S12 may specifically include a step of forming a first extension portion 141 to obtain a first polar electrode 14 including the first extension portion 141, in which the first extension portion 141 extends from a sidewall of the third semiconductor layer 131 to the first semiconductor layer 111 along a sidewall of the first film layer structure, and the first film layer structure is a film layer structure between the first semiconductor layer 111 and the third semiconductor layer 131.

In some specific embodiments, as shown in FIGS. 1 to 4, the manufacturing method of the light-emitting diode chip 10 may further include a step of offsetting inwardly the sidewall of the third semiconductor layer 131 and the sidewall of the first film layer structure before forming the first extension portion 141 to form a first step structure, in which the step surface F1 of the first step structure is the first semiconductor layer 111, and the first extension portion 141 extends from the sidewall of the third semiconductor layer 131 along the sidewall of the first film layer structure to the step surface F1 of the first step structure.

Specifically, as shown in FIGS. 1 to 4, the manufacturing method of the light-emitting diode chip 10 may further include a step of forming a first contact portion 142 to obtain a first polar electrode 14 including the first extension portion 141 and the first contact portion 142, in which the first contact portion 142 is connected to the first extension portion 141 and is in contact with a surface of the third semiconductor layer 131 which faces away from the reflective layer 12.

In particular implementation, the manufacturing method of the light-emitting diode chip 10 may further include a step of forming the first insulating layer 16 on the sidewall of the first film layer structure before forming the first extension portion 141. The first insulating layer 16 may electrically isolates the first extension portion 141 and the first film layer structure.

At step S13, a second polar electrode 15 (shown in FIGS. 1 to 5) electrically connecting the second semiconductor layer 113 and the fourth semiconductor layer 133 is formed.

In some embodiments, as shown in FIGS. 1 to 4, the step S13 may specifically include a step of forming the second extension portion 151 to obtain the second polar electrode 15 including the second extension portion 151, in which the second extension portion 151 extends from the sidewall of the fourth semiconductor layer 133 to the second semiconductor layer 113 along the sidewall of the second film layer structure, and the second film layer structure is a film layer structure between the second semiconductor layer 113 and the fourth semiconductor layer 133.

In some specific embodiments, as shown in FIGS. 1 to 4, the manufacturing method of the light-emitting diode chip 10 may further include a step of offsetting inwardly the sidewall of the fourth semiconductor layer 133 and the sidewall of the second film layer structure before forming the second extension portion 151 to form a second step structure, in which the step surface F2 of the second step structure is the second semiconductor layer 113, and the second extension portion 151 extends from the sidewall of the fourth semiconductor layer 133 along the sidewall of the second film layer structure to the step surface F2 of the second step structure.

Specifically, as shown in FIGS. 1 to 4, the manufacturing method of the light-emitting diode chip 10 may further include a step of forming a second contact portion 152 when the second extension portion 151 is formed, to obtain a second polar electrode 15 including the second extension portion 151 and the second contact portion 152, in which the second contact portion 152 is connected to the second extension portion 151 and is in contact with a surface of the fourth semiconductor layer 133 which faces away from the reflective layer 12.

In particular implementation, the manufacturing method of the light-emitting diode chip 10 may further include a step of forming the second insulating layer 17 on the sidewall of the second film layer structure before forming the second extension portion 151. The second insulating layer 17 can electrically isolate the second extension portion 151 and the second film layer structure.

In other embodiments, as shown in FIG. 5, before step S12, the manufacturing method of the light-emitting diode chip 10 may further include a step of forming a first interlayer via 21 extending through the third semiconductor layer 131 and a film layer structure (i.e., a first film layer structure) between the third semiconductor layer 131 and the first semiconductor layer 111.

Accordingly, step S12 may specifically include a step of forming the first polar electrode 14 filling the first interlayer via 21 on the surface of the third semiconductor layer 131 which faces away from the reflective layer 12.

In particular, the manufacturing method of the light-emitting diode chip 10 may further include a step of forming a third insulating layer on the inner wall of the first interlayer via 21 before forming the first polar electrode 14. Here, the third insulating layer may electrically isolate the first polar electrode 14 filling the first interlayer via 21 from the first film layer structure.

In other embodiments, as shown in FIG. 5, before step S13, the manufacturing method of the light-emitting diode chip 10 may further include a step of forming a second interlayer via 20 extending through the fourth semiconductor layer 133 and a film layer structure (i.e., a second film layer structure) between the fourth semiconductor layer 133 and the second semiconductor layer 113.

Accordingly, step S13 may specifically include a step of forming a second polar electrode 15 filling the second interlayer via 20 on the surface of the fourth semiconductor layer 133 which faces away from the reflective layer 12.

In particular, the manufacturing method of the light-emitting diode chip 10 may further include a step of forming a fourth insulating layer on the inner wall of the second interlayer via 20 before forming the second polar electrode 15. Here, the fourth insulating layer may electrically isolate the second polar electrode 15 filling the second interlayer via 20 from the second film layer structure.

It should be noted that, for a specific configuration of the light-emitting diode chip 10 in this embodiment, reference may be made to the specific embodiments of the light-emitting diode chip, and therefore details are not described herein.

As may be seen from the above, the manufacturing method of the light-emitting diode chip according to the present embodiment includes steps of forming a light-emitting diode epitaxial wafer including a substrate, a first epitaxial light-emitting structure, a reflective layer and a second epitaxial structure, in which the first epitaxial light-emitting structure is formed on a side of the substrate and includes a first semiconductor layer, a first light-emitting layer and a second semiconductor layer stacked sequentially, the reflective layer is formed on a side of the first epitaxial light-emitting structure which faces away from the substrate, and the second epitaxial light-emitting structure is formed on a side of the reflective layer which faces away from the first epitaxial light-emitting structure and includes a third semiconductor layer, a second light-emitting layer and a fourth semiconductor layer stacked sequentially, the first semiconductor layer and the third semiconductor layer have first polarities and the second semiconductor layer and the fourth semiconductor layer have second polarities; forming a first polar electrode electrically connecting the first semiconductor layer and the third semiconductor layer; and forming a second polar electrode electrically connecting the second semiconductor layer and the fourth semiconductor layer. In this way, a single light-emitting diode chip has a double-sided light-emitting characteristic, thereby enabling the light-emitting diode display to realize the double-sided displaying function by using the light-emitting diode backplane, and further greatly reducing the thickness, the weight, and the cost of the double-sided display, and thus improving the market competitiveness of the product.

Referring to FIG. 8, FIG. 8 is a schematic structural diagram of a light-emitting diode display according to embodiments of the present application. As shown in FIG. 8, the light-emitting diode display 200 may include a driving substrate 201 and a light-emitting diode chip 10 (as shown in FIGS. 1 to 5) of any of the above-described embodiments. The light-emitting diode chip 10 is electrically connected to the driving substrate 201, and the driving substrate 201 is used to drive the light-emitting diode chip 10 to emit light.

Specifically, as shown in FIGS. 1 to 5, the light-emitting diode chip 10 may include a first epitaxial light-emitting structure 11, a reflective layer 12, a second epitaxial light-emitting structure 13, a first polar electrode 14, and a second polar electrode 15. The first epitaxial light-emitting structure 11 includes a first semiconductor layer 111, a first light-emitting layer 112, and a second semiconductor layer 113, which are sequentially stacked. The reflective layer 12 is located on a side of the first epitaxial light-emitting structure 11. The second epitaxial light-emitting structure 13 is located on a side of the reflective layer 12 which faces away from the first epitaxial light-emitting structure 11, and includes a third semiconductor layer 131, a second light-emitting layer 132, and a fourth semiconductor layer 133, which are sequentially stacked. The first semiconductor layer 111 and the third semiconductor layer 131 each have a first polarity, and the second semiconductor layer 113 and the fourth semiconductor layer 133 each have a second polarity. The first polar electrode 14 is electrically connected to the first semiconductor layer 111 and the third semiconductor layer 131, and the second polar electrode 15 is electrically connected to the second semiconductor layer 113 and the fourth semiconductor layer 133.

In particular implementation, a side of the second epitaxial light-emitting structure 13 of the light-emitting diode chip 10 which faces away from the reflective layer 12 may be disposed toward the driving substrate 201. The light rays emitted by the second epitaxial light-emitting structure 13 may be transmitted through the driving substrate 201 directly or may be transmitted through the driving substrate 201 after being reflected by the reflective layer 12, and then may be emitted out from the back surface of the light-emitting diode display 200. So, the back surface displaying function of the light-emitting diode display 200 is realized.

Meanwhile, the light rays emitted from the first epitaxial light-emitting structure 11 in the light-emitting diode chip 10 may be emitted out from the front surface of the light-emitting diode display 200 directly or after being reflected by the reflective layer 12, so as to realize the front surface displaying function of the light-emitting diode display 200.

In some embodiments, as shown in FIG. 8, the light-emitting diode display 200 may further include a pixel defining layer 202, a first bonding electrode 203, and a second bonding electrode 204. The pixel defining layer 202 is provided on a side of the driving substrate 201. The side of pixel defining layer 202 which faces away from the driving substrate 201 may be provided with a groove 202A. At least a portion of the light-emitting diode chip 10 may be located in the groove 202A. The grooves 202A may extend through the pixel defining layer 202. The first bonding electrode 203 and the second bonding electrode 204 may be provided insulatingly at intervals and electrically connected to the driving substrate 201. Specifically, the first bonding electrode 203 and the second bonding electrode 204 are provided on the inner walls of the grooves 202A and electrically connected to the first polar electrode 14 and the second polar electrode 15, respectively.

In some examples, the pixel defining layer 202 may be a planarization layer for planarizing the drive substrate 201.

In some specific embodiments, as shown in FIGS. 1 to 4, in the light-emitting diode chip 10, a part of the first polar electrode 14 or the whole first polar electrode 14 may be provided on the sidewall of the first semiconductor layer 111, the sidewall of the third semiconductor layer 131, and the sidewall of the first film layer structure. The first film layer structure is a film layer structure between the first semiconductor layer 111 and the third semiconductor layer 131. Accordingly, as shown in FIG. 8, at least a part of the first bonding electrode 203 may be provided on the inner sidewall of the groove 202A. The first bonding electrode 203 located on the inner sidewall of the groove 202A may be in contact with the first polar electrode 14 located on the sidewall of the first semiconductor layer 111, the sidewall of the third semiconductor layer 131, and the sidewall of the first film layer structure. So, the electrical connection between the first polar electrode 14 and the first bonding electrode 203 may be realized.

In some specific embodiments, as shown in FIGS. 1 to 4, in the light-emitting diode chip 10, a part of the second polar electrode 15 or the whole second polar electrode 15 may be provided on the sidewall of the second semiconductor layer 113, the sidewall of the fourth semiconductor layer 133, and the sidewall of the second film layer structure. The second film layer structure is a film layer structure between the second semiconductor layer 113 and the fourth semiconductor layer 133. Accordingly, as shown in FIG. 8, at least a part of the second bonding electrode 204 may be provided on the inner sidewall of the groove 202A. The second bonding electrode 204 located on the inner sidewall of the groove 202A may be in contact with the second polar electrode 15 located on the sidewall of the second semiconductor layer 113, the sidewall of the fourth semiconductor layer 133, and the sidewall of the second film layer structure. So, the electrical connection between the second polar electrode 15 and the second bonding electrode 204 may be realized.

In other embodiments, as shown in FIG. 5, in the light-emitting diode chip 10, the first polar electrode 14 may also be formed on the surface of the second epitaxial light-emitting structure 13 which faces away from the reflective layer 12, and the first polar electrode 14 may be a transparent electrode. Accordingly, at least a part of the first bonding electrode 203 may be provided on the inner bottom wall of the groove 202A. The first bonding electrode 203 located on the inner bottom wall of the groove 202A may be in contact with the first polar electrode 14 located on the surface of the second epitaxial light-emitting structure 13 which faces away from the reflective layer 12. So, the electrical connection between the first polar electrode 14 and the first bonding electrode 203 may be realized.

In other embodiments, as shown in FIG. 5, in the light-emitting diode chip 10, the second polar electrode 15 may also be formed on the surface of the second epitaxial light-emitting structure 13 which faces away from the reflective layer 12, and the second polar electrode 15 may be a transparent electrode. Accordingly, at least a part of the second bonding electrode 204 may be provided on the inner bottom wall of the groove 202A. The second bonding electrode 204 located on the inner bottom wall of the groove 202A may be in contact with the second polar electrode 15 located on the surface of the second epitaxial light-emitting structure 13 which faces away from the reflective layer 12. So, the electrical connection between the first polar electrode 14 and the second polar electrode 15 may be realized.

It should be noted that, according to the light-emitting diode display provided in the embodiments of the present application, the double-sided light-emitting diode chip provided in the embodiments of the present application is provided, so that the double-sided displaying function may be realized by using only one light-emitting diode backplane, which greatly reduces the thickness, the weight, and the cost of the double-sided display, thereby improving the market competitiveness of the product.

The foregoing description is merely illustrative of the preferred embodiments of the present application and is not intended to limit the application, and any modifications, equivalents, and modifications that fall within the spirit and principles of the present application are intended to be included within the scope of the present application.

1. A light-emitting diode chip comprising:
a first epitaxial light-emitting structure comprising a first semiconductor layer, a first light-emitting layer, and a second semiconductor layer stacked in sequence;
a reflective layer at a side of the first epitaxial light-emitting structure;
a second epitaxial light-emitting structure located at a side of the reflective layer which faces away from the first epitaxial light-emitting structure, and comprising a third semiconductor layer, a second light-emitting layer, and a fourth semiconductor layer that are sequentially stacked, wherein the first semiconductor layer and the third semiconductor layer have first polarities, and the second semiconductor layer and the fourth semiconductor layer have second polarities;
a first polar electrode electrically connecting the first semiconductor layer and the third semiconductor layer; and
a second polar electrode electrically connecting the second semiconductor layer and the fourth semiconductor layer.

2. The light-emitting diode chip according to claim 1, further comprising:
a first Bragg reflective layer between the first epitaxial light-emitting structure and the reflective layer; and
a second Bragg reflective layer between the second epitaxial light-emitting structure and the reflective layer.

3. The light-emitting diode chip according to claim 1, wherein the first polar electrode comprises a first extension portion extending from a sidewall of the third semiconductor layer along a sidewall of a first film layer structure to the first semiconductor layer, wherein the first film layer structure is a film layer structure between the first semiconductor layer and the third semiconductor layer; the second polar electrode comprises a second extension portion extending from a sidewall of the fourth semiconductor layer along a sidewall of a second film layer structure to the second semiconductor layer, wherein the second film layer structure is a film layer structure between the second semiconductor layer and the fourth semiconductor layer.

4. The light-emitting diode chip according to claim 3, wherein the sidewall of the third semiconductor layer, a sidewall of the first film layer structure, and a sidewall of the first semiconductor layer are connected together to form a first step structure, a step surface of the first step structure is the first semiconductor layer, and the first extension portion extends from the sidewall of the third semiconductor layer along the sidewall of the first film layer structure to the step surface of the first step structure.

5. The light-emitting diode chip according to claim 3, wherein the sidewall of the fourth semiconductor layer, a sidewall of the second film layer structure, and a sidewall of the second semiconductor layer are connected together to form a second step structure, a step surface of the second step structure is the second semiconductor layer, and the second extension portion extends from the sidewall of the fourth semiconductor layer to the step surface of the second step structure along the sidewall of the second film layer structure.

6. The light-emitting diode chip according to claim 3, wherein the first polar electrode further comprises a first contact portion connected to the first extension portion and in contact with a surface of the third semiconductor layer which faces away from the reflective layer; the second polar electrode further comprises a second contact portion connected to the second extension portion and in contact with a surface of the fourth semiconductor layer which faces away from the reflective layer.

7. The light-emitting diode chip according to claim 3, further comprising:
a first insulating layer that is located between the first extension portion and the first film layer structure and electrically isolates the first extension portion from the first film layer structure; and
a second insulating layer that is located between the second extension portion and the second film layer structure, and that electrically isolates the second extension portion from the second film layer structure.

8. The light-emitting diode chip according to claim 1, further comprising:
a first interlayer via extending through the third semiconductor layer and a first film layer structure located between the third semiconductor layer and the first semiconductor layer, wherein the first polar electrode is located on a surface of the third semiconductor layer which faces away from the reflective layer and electrically connected to the first semiconductor layer through the first interlayer via; and
a second interlayer via extending through the fourth semiconductor layer and a second film layer structure between the fourth semiconductor layer and the second semiconductor layer, wherein the second polar electrode is located on a surface of the fourth semiconductor layer which faces away from the reflective layer and electrically connected to the second semiconductor layer through the second interlayer via.

9. A manufacturing method of a light-emitting diode chip comprises:
forming a light-emitting diode epitaxial wafer comprising a substrate, a first epitaxial light-emitting structure, a reflective layer and a second epitaxial light-emitting structure, wherein the first epitaxial light-emitting structure is formed on a side of the substrate and comprises a first semiconductor layer, a first light-emitting layer and a second semiconductor layer, wherein the reflective layer is formed on a side of the first epitaxial light-emitting structure which faces away from the substrate, and the second epitaxial light-emitting structure is formed on a side of the reflective layer which faces away from the first epitaxial light-emitting structure and comprises a third semiconductor layer, a second light-emitting layer and a fourth semiconductor layer, wherein the first semiconductor layer and the third semiconductor layer have first polarities and the second semiconductor layer and the fourth semiconductor layer have second polarities;
forming a first polar electrode electrically connecting the first semiconductor layer and the third semiconductor layer; and
forming a second polar electrode electrically connecting the second semiconductor layer and the fourth semiconductor layer.

10. The manufacturing method according to claim 9, wherein the forming the first polar electrode comprises:
forming a first extension portion to obtain the first polar electrode comprising the first extension portion, wherein the first extension portion extends from a sidewall of the third semiconductor layer along a sidewall of a first film layer structure to the first semiconductor layer, the first film layer structure is a film layer structure between the first semiconductor layer and the third semiconductor layer;
the forming the second polar electrode comprises:
forming a second extension portion to obtain the second polar electrode comprising the second extension portion, wherein the second extension portion extends from a sidewall of the fourth semiconductor layer along a sidewall of a second film layer structure to the second semiconductor layer, the second film layer structure is a film layer structure between the second semiconductor layer and the fourth semiconductor layer.

11. The manufacturing method according to claim 9, wherein before forming the first polar electrode, the manufacturing method further comprises:
forming a first interlayer via extending through the third semiconductor layer and a first film layer structure between the third semiconductor layer and the first semiconductor layer;
the forming the first polar electrode comprises:
forming the first polar electrode filling the first interlayer via on a surface of the third semiconductor layer which faces away from the reflective layer.

12. The manufacturing method according to claim 9, wherein before forming the second polar electrode, the manufacturing method further comprises:
forming a second interlayer via extending through the fourth semiconductor layer and a second film layer structure between the fourth semiconductor layer and the second semiconductor layer;
the forming the second polar electrode comprises:
forming the second polar electrode filling the interlayer via on a surface of the fourth semiconductor layer which faces away from the reflective layer.

13. A light-emitting diode display comprising:
a driving substrate; and
a light-emitting diode chip comprising:
a first epitaxial light-emitting structure comprising a first semiconductor layer, a first light-emitting layer, and a second semiconductor layer stacked in sequence;
a reflective layer at a side of the first epitaxial light-emitting structure;
a second epitaxial light-emitting structure located at a side of the reflective layer which faces away from the first epitaxial light-emitting structure, and comprising a third semiconductor layer, a second light-emitting layer, and a fourth semiconductor layer that are sequentially stacked, wherein the first semiconductor layer and the third semiconductor layer have first polarities, and the second semiconductor layer and the fourth semiconductor layer have second polarities;
a first polar electrode electrically connecting the first semiconductor layer and the third semiconductor layer; and
a second polar electrode electrically connecting the second semiconductor layer and the fourth semiconductor layer;
wherein the light-emitting diode chip is electrically connected to the driving substrate, and the driving substrate is configured to drive the light-emitting diode chip to emit light.

14. The light-emitting diode display according to claim 13, further comprising:
a pixel defining layer provided on a side of the driving substrate, wherein a side of the pixel defining layer which faces away from the driving substrate is provided with a groove, and at least a part of the light-emitting diode chip is located in the groove;
a first bonding electrode disposed on an inner wall of the groove and electrically connected to the first polar electrode of the light-emitting diode chip; and
a second bonding electrode disposed on the inner wall of the groove and electrically connected to the second polar electrode of the light-emitting diode chip.

15. The light-emitting diode display according to claim 13, wherein the light-emitting diode chip further comprises:
a first Bragg reflective layer between the first epitaxial light-emitting structure and the reflective layer; and
a second Bragg reflective layer between the second epitaxial light-emitting structure and the reflective layer.

16. The light-emitting diode display according to claim 13, wherein the first polar electrode comprises a first extension portion extending from a sidewall of the third semiconductor layer along a sidewall of a first film layer structure to the first semiconductor layer, wherein the first film layer structure is a film layer structure between the first semiconductor layer and the third semiconductor layer; the second polar electrode comprises a second extension portion extending from a sidewall of the fourth semiconductor layer along a sidewall of a second film layer structure to the second semiconductor layer, wherein the second film layer structure is a film layer structure between the second semiconductor layer and the fourth semiconductor layer.

17. The light-emitting diode display according to claim 16, wherein the sidewall of the third semiconductor layer, a sidewall of the first film layer structure, and a sidewall of the first semiconductor layer are connected together to form a first step structure, a step surface of the first step structure is the first semiconductor layer, and the first extension portion extends from the sidewall of the third semiconductor layer along the sidewall of the first film layer structure to the step surface of the first step structure.

18. The light-emitting diode display according to claim 16, wherein the sidewall of the fourth semiconductor layer, a sidewall of the second film layer structure, and a sidewall of the second semiconductor layer are connected together to form a second step structure, a step surface of the second step structure is the second semiconductor layer, and the second extension portion extends from the sidewall of the fourth semiconductor layer to the step surface of the second step structure along the sidewall of the second film layer structure.

19. The light-emitting diode display according to claim 16, wherein the first polar electrode further comprises a first contact portion connected to the first extension portion and in contact with a surface of the third semiconductor layer which faces away from the reflective layer; the second polar electrode further comprises a second contact portion connected to the second extension portion and in contact with a surface of the fourth semiconductor layer which faces away from the reflective layer.

20. The light-emitting diode display according to claim 16, wherein the light-emitting diode chip further comprises:
a first insulating layer that is located between the first extension portion and the first film layer structure and electrically isolates the first extension portion from the first film layer structure; and
a second insulating layer that is located between the second extension portion and the second film layer structure, and that electrically isolates the second extension portion from the second film layer structure.
